(19) United States
(12) Patent Application Publication
(10) Pub. No.: US 2021/0243910 A1
(43) Pub. Date: Aug. 5, 2021

(54) PROTECTIVE MEMBER AND ELECTRONIC EQUIPMENT

(71) Applicant: DENSO CORPORATION, Kariya-city (JP)

(72) Inventor: Fumiyasu FURUSE, Kariya-city (JP)

(21) Appl. No.: 17/238,738

(22) Filed: Apr. 23, 2021

Related U.S. Application Data
(63) Continuation of application No. PCT/JP2019/044706, filed on Nov. 14, 2019.

(30) Foreign Application Priority Data
Dec. 11, 2018 (JP) 2018-231708

(51) Int. Cl. H05K 5/03; H05K 5/00; H01H 13/14; H01H 13/04

(52) U.S. Cl. CPC H05K 5/03; H05K 5/0017; H01H 2231/016; H01H 13/04; H01H 13/14

(57) ABSTRACT

A protective member includes a protective film having a base material layer and an adhesive layer, and a separator that is attached to the entire side of the adhesive layer before using the protective film and that partly peels off from the adhesive layer and the rest does not peel off when using the protective film. When the protective film is attached to a display surface provided on the overlay cover and a surface of a front panel where a top surface of a push plate of a push-type switch is exposed from an opening of the overlay cover, the adhesive layer is attached to a part of the surface of the overlay cover and is not adhered to the upper surface of the push plate of the push-type switch and a periphery of the upper surface.

### CROSS REFERENCE TO RELATED APPLICATIONS

This application is a continuation application of International Patent Application No. PCT/JP2019/044706 filed on Nov. 14, 2019, which designated the U.S. and based on and claims the benefits of priority of Japanese Patent Application No. 2018-231708 filed on Dec. 11, 2018. The entire disclosure of all of the above applications is incorporated herein by reference.

### TECHNICAL FIELD

The present disclosure relates to a protective member and an electronic equipment.

### BACKGROUND

In an electronic equipment having a display, a protective film is attached to a surface of the display in order to prevent scratches and dirt from adhering to the surface of the display.

### SUMMARY

According to the present disclosure, an object of the present disclosure is to provide a protective member and an electronic equipment that properly operate push-type switch while properly avoiding deterioration of a visibility and appearance of a display surface by attaching a protective film to a surface of a front panel of the electronic equipment.

According to one aspect of the present disclosure, a protective film having a base material layer and an adhesive layer to which an adhesive is applied to the base material layer, and a separator that is attached to the entire side of the adhesive layer before using the protective film and is attached to the entire surface of the adhesive layer before the protective film is used and that partly peels off from the adhesive layer and the rest does not peel off when the protective film is used are provided. When the protective film is attached to a display surface provided on the overlay cover is provided with the display surface and a surface of a front panel where a top surface of a push plate of a push-type switch is exposed from an opening of the overlay cover, the protective film is attached to the surface of the front panel so that the adhesive layer is not adhered to the surface of the overlay cover and the adhesive layer is not adhered to the upper surface of the push plate of the push-type switch and a periphery of the upper surface.

According to one aspect of the present disclosure, a front panel and a protective film are provided, the front panel has a display surface on the overlay cover and the upper surface of the push plate of the push-type switch is exposed from the opening, and the protective film has a base material layer and an adhesive layer which is adhesive attached to the base material layer. The protective film is attached to the surface of the front panel so that the adhesive layer is adhered to a part of the surface of the overlay cover and the adhesive layer is not adhered to the upper surface of the push plate of the push-type switch and the periphery of the upper surface.

### BRIEF DESCRIPTION OF DRAWINGS

The above and other objects, features and advantages of the present disclosure will become more apparent from the following detailed description made with reference to the accompanying drawings. In the drawings:

FIG. 1 is a diagram showing an embodiment in which a center display device is arranged in a vehicle;

FIG. 2 is a front view of an overlay cover;

FIG. 3 is a cross-sectional view of a protective member;

FIG. 4 is a front view of the protective member;

FIG. 5 is a cross-sectional view (first state) of the push-type switch and its surroundings;

FIG. 6 is a cross-sectional view (second state) of the push-type switch and its surroundings;

FIG. 7 is a diagram showing an adhesive portion and a non-adhesive portion of the overlay cover;

FIG. 8 is a cross-sectional view (first state) of the push-type switch and its surroundings with the protective film attached;

FIG. 9 is a cross-sectional view (second state) of the push-type switch and its surroundings with the protective film attached; and

FIG. 10 is a diagram showing an appearance in which a management label is attached.

### DETAILED DESCRIPTION

In an assumable example, an electronic device having a display, has a configuration in which a protective film is attached to a display surface in order to prevent scratches and dirt from adhering to the display surface. The protective film has a base material layer made of a transparent and flexible resin and an adhesive layer in which an adhesive is applied to an entire one side of the base material layer. Before use, a separator is attached to the entire surface of the adhesive layer. When the protective film is used, the separator is peeled off from the adhesive layer to expose the adhesive layer, and the exposed adhesive layer is adhered to the display surface.

For example, in a center display device arranged on a dashboard of the vehicle, a part of a transparent overlay cover is used as a screen display portion, and the display surface is arranged so as to face the screen display portion. At the same time, a push-type switch that can be pressed by an user may be arranged around the surface of the display. In this case, an opening is formed in the overlay cover, and the upper surface of the push plate of the push-type switch is exposed from the opening to form the front panel. In such a configuration, the adhesive layer adheres to the entire surface of the front panel, so that the protective film is attached to the screen display portion to prevent scratches and dirt from adhering to the screen display portion, and it is possible to avoid deterioration of visibility and appearance of the display surface.

In the configuration in which the adhesive layer is adhered to the entire surface of the front panel, the adhesive layer is adhered not only to the screen display portion but also to the upper surface of the push plate of the push-type switch and the periphery of the upper surface. Therefore, there is a concern that the push plate cannot be pressed due to the tension of the protective film. Further, even if the push plate can be pressed, there is a concern that the push plate does not return to the original position due to the adhesive force of the protective film.

According to the present disclosure, an object of the present disclosure is to provide a protective member and an electronic equipment that properly operate push-type switch while properly avoiding deterioration of a visibility and appearance of a display surface by attaching a protective film to a surface of a front panel of the electronic equipment.

According to one aspect of the present disclosure, a protective film having a base material layer and an adhesive layer to which an adhesive is applied to the base material layer, and a separator that is attached to the entire side of the adhesive layer before using the protective film and is attached to the entire surface of the adhesive layer before the protective film is used and that partly peels off from the adhesive layer and the rest does not peel off when the protective film is used are provided. When the protective film is attached to a display surface provided on the overlay cover is provided with the display surface and a surface of a front panel where a top surface of a push plate of a push-type switch is exposed from an opening of the overlay cover, the protective film is attached to the surface of the front panel so that the adhesive layer is not adhered to the surface of the overlay cover and the adhesive layer is not adhered to the upper surface of the push plate of the push-type switch and a periphery of the upper surface.

Since the adhesive layer is adhered to a part of the surface of the overlay cover, and the protective film is adhered to the surface of the front panel, it is possible to appropriately avoid deterioration of the visibility and appearance of the display surface. Since the adhesive layer is prevented from adhering to the upper surface of the push plate of the push-type switch and the periphery of the upper surface, the tension and the adhesive force of the protective film do not act, and the push-type switch can be operated appropriately. As a result, the protective film is attached to the surface of the front panel of the electronic device, so that the push-type switch can be operated appropriately while appropriately avoiding deterioration of the visibility and appearance of the display surface.

According to one aspect of the present disclosure, a front panel and a protective film are provided, the front panel has a display surface on the overlay cover and the upper surface of the push plate of the push-type switch is exposed from the opening, and the protective film has a base material layer and an adhesive layer which is adhesive attached to the base material layer. The protective film is attached to the surface of the front panel so that the adhesive layer is adhered to a part of the surface of the overlay cover and the adhesive layer is not adhered to the upper surface of the push plate of the push-type switch and the periphery of the upper surface.

Since the protective film is attached to the surface of the front panel of the electronic device, the push-type switch can be operated appropriately while appropriately avoiding deterioration of the visibility and appearance of the display surface.

Hereinafter, an embodiment will be described with reference to the drawings.

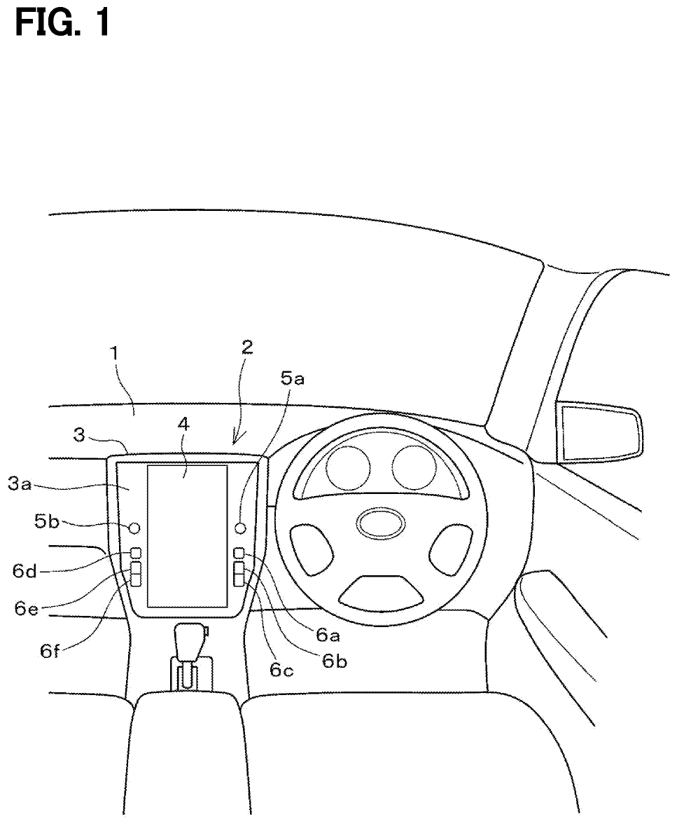

As shown in FIG. 1, a center display device 2 (electronic equipment) is arranged on a dashboard 1 in a vehicle interior. A display surface 4 is provided on a surface 3a of a front panel 3 of the center display device 2, and operation knobs 5a and 5b of rotary switches and upper surfaces of push plates 6a to 6f of the push-type switch are exposed. An occupant can operate the operation knobs 5a and 5b of the rotary switches and the push plates 6a to 6f of the push-type switches on the front panel 3 of the center display device 2.

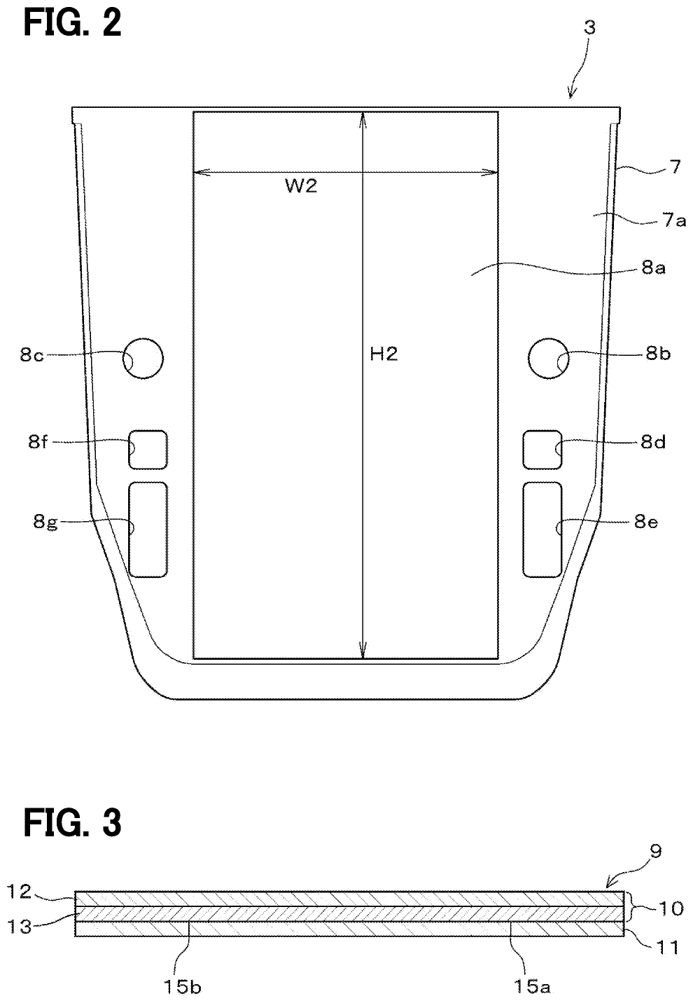

As shown in FIG. 2, the front panel 3 is provided with a rectangular screen display portion 8a at the center of an overlay cover 7 having a predetermined shape, and a plurality of openings 8b to 8g beside the screen display portion 8a are formed. The overlay cover 7 is molded of a transparent resin, and a portion other than the screen display portion 8a is colored with, for example, black ink. For example, in a state where the front panel 3 is attached to a main body of the device (not shown) by screwing or the like, the display surface 4 faces the screen display portion 8a, the rotary switch operation knobs 5a and 5b are exposed from the circular openings 8b and 8c, and upper surfaces of the push plates 6a to 6f of the push-type switch are exposed from the rectangular openings 8d to 8g. That is, an occupant can visually recognize the display surface 4 through the screen display portion 8a. The upper surfaces of the push plates 6a and 6d of one push-type switch are exposed from the openings 8d and 8f, and the upper surfaces of the push plates 6b, 6c, 6e and 6f of the two push-type switches are exposed from the openings 8e and 8g. As shown in FIG. 1, the operation knob 5a of the rotary switch and the push plates 6a to 6c of the push-type switch are arranged on a right side of the display surface 4 when viewed from the occupant, and the operation knob 5b of the rotary switch and the push plates 6d to 6f of the push-type switch are arranged on a left side of the display surface 4.

On the display surface 4, for example, a map screen for a navigation function, a setting screen for an audio function, a setting screen for an air conditioner function, and the like are displayed, and various touch buttons are displayed on each screen. In the overlay cover 7, the screen display portion 8a has a capacitance type touch sensor, and when the user touches a portion of the screen display portion 8a corresponding to the touch button, the touch operation is detected. The rotary switch is, for example, a volume switch for adjusting the volume, a tune switch for selecting a radio receiving station, or the like. The push-type switch is, for example, a switch for selecting or determining various items.

When the front panel 3 is attached to the main body of the device, the operation knobs 5a and 5b of the rotary switch project forward (in an occupant direction) from the surface 7a of the overlay cover 7, and the display surface 4 and the upper surface of the push plates 6a to 6f of the push-type switch are substantially flush with the surface 7a of the overlay cover 7. The term “substantially flush” as used herein means not only a perfect same plan but also a state in which the display surface 4 and the upper surfaces of the push plates 6a to 6f of the push-type switch are slightly recessed or convex from the surface 7a of the overlay cover 7. Further, the surface 7a of the overlay cover 7 is not a perfect flat surface but has a slightly curved shape, and has a curved structure that is slightly convex in the vertical direction and slightly convex in the horizontal direction.

In a manufacturing process and a delivery process until the vehicle reaches the user, a protective film is attached to the surface 3a of the front panel 3 on the vehicle manufacturer side in order to prevent scratches and dirt from adhering to the screen display portion 8a facing the display surface 4. After the user purchases the vehicle, a protective film may be attached by the user himself/herself in order to prevent scratches and dirt from adhering to the screen display portion 8a facing the display surface 4.

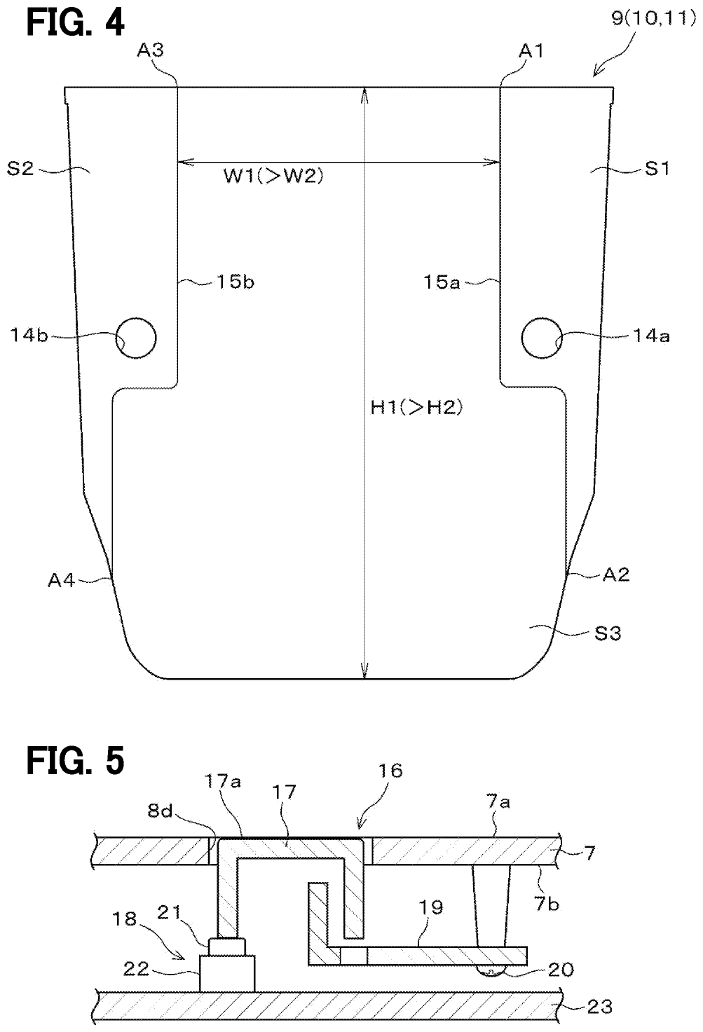

Hereinafter, the protective film will be described. As shown in FIG. 3, the protective member 9 is configured such that a separator 11 is attached to the entire one side of a protective film 10. The protective film 10 is used by peeling the separator 11 from the protective film 10. As shown in FIG. 4, the outer shapes of the protective film 10 and the separator 11 are substantially the same as the outer shapes of the front panel 3. The term “substantially the same” as used herein includes not only the meaning of completely the same shape but also the meaning of a slightly different shape. The protective film 10 is formed with circular openings 14a and 14b through which the operation knobs 5a and 5b of the rotary switch described above are inserted when the protective film 10 is attached to the surface 3a of the front panel 3. Since the portions corresponding to the openings 14a and 14b are peeled off from the protective film 10 as described later, the openings corresponding to the openings 14a and 14b are not formed in the separator 11.

The protective film 10 has a base material layer 12 and an adhesive layer 13 on which an adhesive is applied to the entire surface of the base material layer 12. The base material layer 12 is a layer that is exposed to the outside in a state where the protective film 10 is attached to the surface 3a of the front panel 3. That is, the base material layer 12 is a layer that actually protects the display surface 4 from scratches and dirt. The adhesive layer 13 is a layer to which the separator 11 is attached before using the adhesive layer 13 and a part of the separator 11 is peeled off at the time of use, and is a layer in which a part of the separator 11 from which the separator 11 has peeled off is attached to the surface 7a of the overlay cover 7.

The base material layer 12 is made of a transparent and flexible resin. That is, with the protective film 10 attached to the surface 3a of the front panel 3, the display surface 4 and the upper surfaces of the push plates 6a to 6f of the push-type switch can be visually recognized, and the base material layer 12 bends when the upper surfaces of the push plates 6a to 6f are pressed. Examples of the resin used for the base material layer 12 include silicon resin, olefin resin, PET (Poly Ethylene Terephthalate) resin and the like.

The adhesive layer 13 is made of a transparent adhesive so that the display surface 4 and the upper surfaces of the push plates of the push-type switches 6a to 6f can be visually recognized when the protective film 10 is attached to the surface 3a of the front panel 3. Further, the adhesive layer 13 is preferably made of an adhesive having high adhesion when the separator 11 is attached and easily peelable when the separator 11 is peeled off. Examples of the adhesive used for the adhesive layer 13 include an acrylic adhesive, a silicon adhesive, etc.

The separator 11 is attached to the adhesive layer 13 before the protective film 10 is used, and as described above, only a part of the separator 11 is peeled off from the adhesive layer 13 when the protective film 10 is used. If the adhesive layer 13 is exposed before the use of the protective film 10, the adhesive strength is reduced. Therefore, the separator 11 is attached to the adhesive layer 13 in order to avoid the reduction in the adhesive strength.

In the present embodiment, as described above, when the protective film 10 is used, the entire part of the separator 11 is not peeled off from the adhesive layer 13, but only a part of the separator 11 is peeled off from the adhesive layer 13. Therefore, a slit is formed so that the portion to be peeled off from the adhesive layer 13 can be easily peeled off. That is, the separator 11 is separated into a portion that is peeled off from the adhesive layer 13 by the slit and a portion that remains without being peeled off. More specifically, as shown in FIG. 4, two slits 15a and 15b are formed, that is, the slit 15a shown by a line A1 to A2 and the slit 15b shown by a line A3 to A4. The portion of S1 on the outside (right side) of the slit 15a and the portion of S2 on the outside (left side) of the slit 15b are the portions that are peeled off from the adhesive layer 13. The portion of S3 which is the inside (left side) of the slit 15a and the inside (right side) of the slit 15b is a portion which remains without being peeled from the adhesive layer 13. A lateral length (W1 in FIG. 4) of the portion remaining without being peeled from the adhesive layer 13 is slightly longer than the lateral length (W2 in FIG. 2) of the screen display portion 8a described above. The vertical length of the portion remaining without being peeled from the adhesive layer 13 (H1 in FIG. 4) is slightly longer than the vertical length of the screen display portion 8a (H2 in FIG. 2). That is, the separator 11 remains without being peeled from the adhesive layer 13 at the portion corresponding to the entire part of the screen display portion 8a.

Like the base material layer 12, the separator 11 is also made of a transparent and flexible resin. That is, with the protective film 10 attached to the surface 3a of the front panel 3, the display surface 4 and the upper surfaces of the push plates 6a to 6f of the push-type switch can be visually recognized, and the separator 11 bends when the upper surfaces of the push plates 6a to 6f are pressed. However, if the base material layer 12 has a certain level of strength, the separator 11 does not need to be as strong as the base material layer 12. Examples of the resin used for the separator 11 include an alkyl resin and a silicon resin.

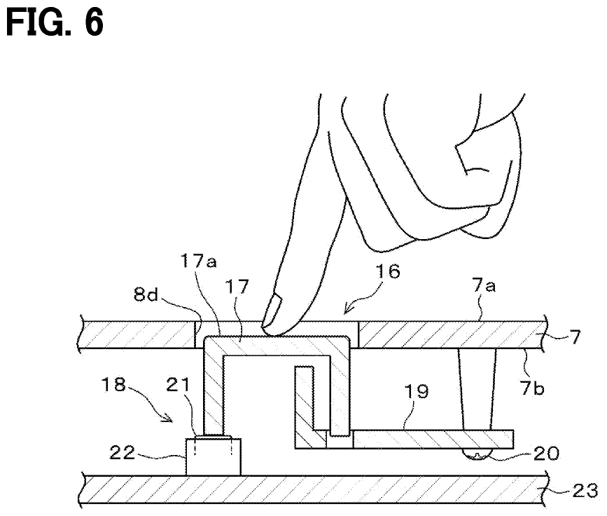

As shown in FIGS. 5 and 6, the push-type switch 16 has a push plate 17 and a tact switch 18. The push plate 17 shown in FIGS. 5 and 6 is the same member as the push plate 6a shown in FIG. 1 in which the upper surface is exposed from the opening 8d of the overlay cover 7. The same applies to the other push plates 6b to 6f shown in FIG. 1 in which the upper surface is exposed from the other openings 8e to 8g of the overlay cover 7. A reflector 19 is screwed to the back surface 7b of the overlay cover 7 with a screw 20. The push plate 17 is supported by the reflector 19 so as to be reciprocally movable in the direction perpendicular to the surface 7a of the overlay cover 7, that is, in the front-rear direction when the center display device 2 is arranged on the dashboard 1. The tact switch 18 has a rubber 21 and a base 22. The rubber 21 is fixed to the tip of the push plate 17 so as to be reciprocally movable integrally with the push plate 17. The base 22 is fixed to a printed circuit board 23.

When the push plate 17 is not pressed, the upper surface 17a of the push plate 17 and the surface 7a of the overlay cover 7 are substantially flush with each other as described above, an electrical contacts are open, and the tact switch 18 is in a off state. When a pressing force from above is applied to the push plate 17, the upper surface 17a of the push plate 17 is recessed from the surface 7a of the overlay cover 7, and the rubber 21 is moved to the base 22 side, so that the electrical contacts becomes from the open state to the close state. The tact switch 18 is turned on. When the pressing force applied to the push plate 17 is released, the upper surface 17a of the push plate 17 that is recessed from the surface 7a of the overlay cover 7 returns to an original position, and the rubber 21 that has been moved to the base 22 side returns to the original position. The electrical contacts return from the closed state to the open state, and the tact switch 18 returns to the off state.

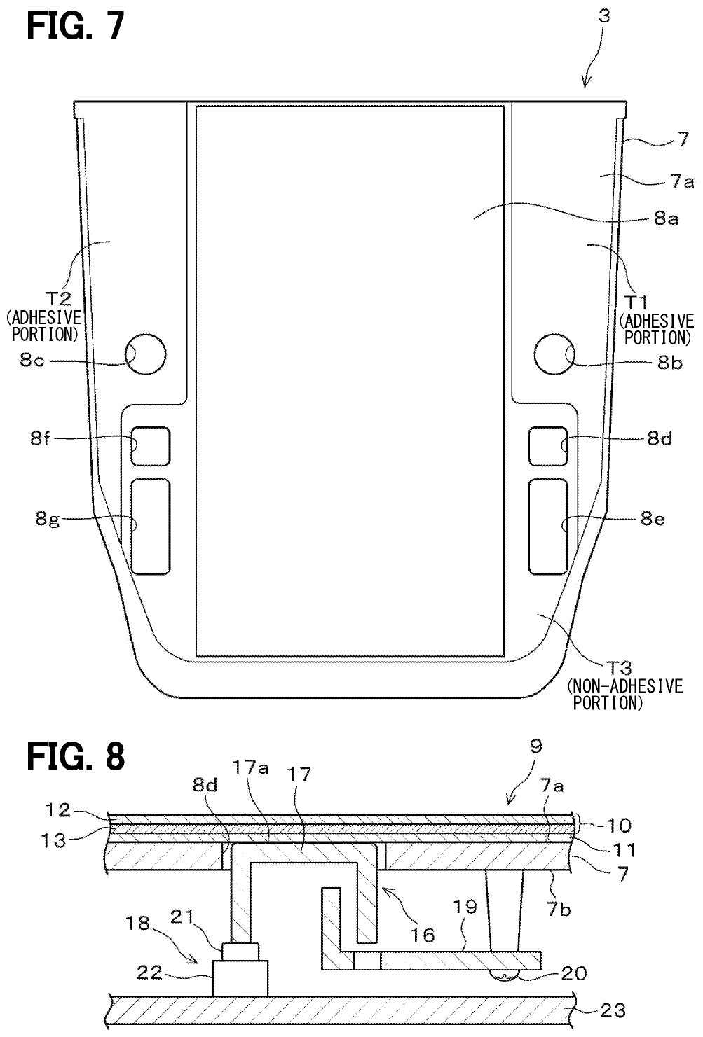

Next, a mode in which the protective film 10 is attached to the surface 3a of the front panel 3 will be described. As shown in FIG. 7, on the surface 7a of the overlay cover 7, the portion (the portion of S1 and S2 shown in FIG. 4) corresponding to the portion (the portion of S1 and S2 shown in FIG. 4) where the separator 11 is peeled off from the adhesive layer 13 when the protective film 10 is the adhesive portions to which the adhesive layer 13 is adhered. Further, on the surface 7a of the overlay cover 7, the portion (T3 portion) corresponding to the portion (S3 portion shown in FIG. 4) where the separator 11 remains without being peeled from the adhesive layer 13 is a non-adhesive portion to which the adhesive layer 13 is not adhered. That is, the screen display portion 8a and the openings 8d to 8g are non-adhesive portions.

In the adhesive layer 13 of the protective film 10, the upper left and right portions from which the separator 11 is peeled off are adhered to the surface 7a of the overlay cover 7. Further, in the adhesive layer 13 of the protective film 10, the central portion and the left and right lower portions where the separator 11 remains without being peeled off are not adhered to the surface 7a of the overlay cover 7.

When the protective film 10 is attached to the surface 3a of the front panel 3, the portions S1 and S2 shown in FIG. 4 of the separator 11 are peeled off from the adhesive layer 13, and the portion S3 of the separator 11 is left without being peeled from the adhesive layer 13. Then, the portions corresponding to the portions S1 and S2 of the adhesive layer 13 of the protective film 10 are aligned with the portions T1 and T2 of the surface 7a of the overlay cover 7, and then the adhesive layer 13 of the protective film 10 is adhered to the surface 7a of the overlay cover 7. At this time, the adhesive layer 13 of the protective film 10 is not adhered to the screen display portion 8a, the upper surface 17a of the push plate 17 of the push-type switch 16, and the periphery of the upper surface 17a. That is, the protective film 10 is attached to the surface 7a of the overlay cover 7 by adhering the adhesive layer 13 at two locations interposing the screen display portion 8a. By providing a certain length in the vertical direction of the portion to which the adhesive layer 13 is adhered, the protective film 10 attached to the surface 3a of the front panel 3 is less likely to be peeled off.

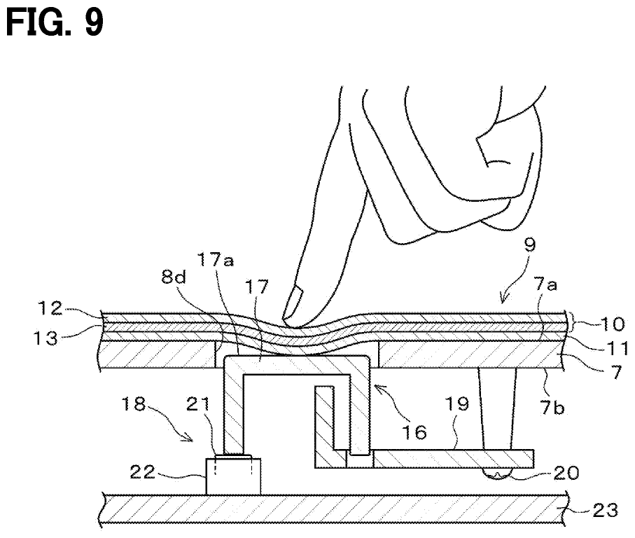

By adhering a part of the adhesive layer 13 to the surface 7a of the overlay cover 7 in this way, the protective film 10 can be attached to the surface 3a of the front panel 3. As shown in FIGS. 8 and 9, when the protective film 10 is attached to the surface 3a of the front panel 3, the separator 11 remains without being peeled off from the upper surface 17a of the push plate 17 of the push-type switch 16 and the periphery of the upper surface 17a. Since the adhesive layer 13 is not adhered to the upper surface 17a of the push plate 17 of the push-type switch 16 and the periphery of the upper surface 17a, the tension or adhesive force of the protective film 10 does not act. Therefore, even when the protective film 10 is attached to the surface 3a of the front panel 3, the push-type switch 16 can be properly operated similar to the case where the protective film 10 is not attached to the surface 3a of the front panel 3 shown in FIGS. 5 and 6. Although the thickness of the protective film 10 and the separator 11 is exaggerated in FIGS. 8 and 9, the thickness of the protective film 10 and the separator 11 is extremely thin with respect to the thickness of the overlay cover 7.

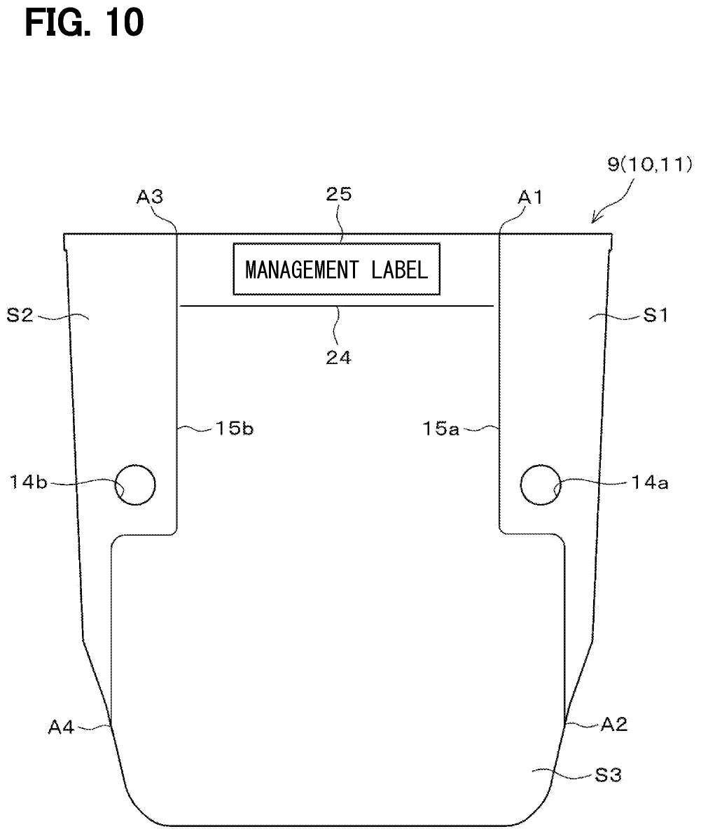

Further, the separator 11 remains without being peeled off in the state where the protective film 10 is attached in this way. Therefore, as shown in FIG. 10, by forming the slit 24 in the separator 11, the slit 24 can be used, for example, as a mark of an attachment position of the management label 25 in a manufacturing process. The slits 15a, 15b, and 24 described above may be formed on the separator 11 by a half-cut method after the separator 11 is attached to the protective film 10, or they may be formed on the separator 11 before the separator 11 is attached to the protective film 10.

When the surface 7a of the overlay cover 7 has a curved structure, and the planar protective film 10 is attached to the surface 7a of the overlay cover 7, the shape of the curved surface 7a of the overlay cover 7 and the shape of the flat protective film 10 does not match, and the protective film 10 floats. Therefore, there is a concern that air bubbles or wrinkles may be generated. In the present embodiment, as compared with the case where the entire adhesive layer 13 is adhered, only a part of the adhesive layer 13 is adhered and the area where the adhesive layer 13 is adhered is small, so that the generation of air bubbles and wrinkles can be suppressed. That is, the larger the area to which the adhesive layer 13 is adhered, the more air bubbles and wrinkles may be generated. However, in the present embodiment, the area to which the adhesive layer 13 is adhered is reduced so that the generation of air bubbles and wrinkles can be suppressed. As a result, it is possible to prevent the appearance from being deteriorated due to the generation of bubbles and wrinkles.

The present embodiment as described above produces the following technical effects. Since the adhesive layer 13 is adhered to a part of the surface 7a of the overlay cover 7, and the protective film 10 is adhered to the surface 3a of the front panel 3, it is possible to appropriately avoid deterioration of the visibility and appearance of the display surface 4. Since the adhesive layer 13 is prevented from adhering to the upper surface 17a of the push plate 17 of the push-type switch 16 and the periphery of the upper surface 17a, the tension and the adhesive force of the protective film 10 do not act, and the push-type switch 16 can be operated appropriately. As a result, the protective film 10 is adhered to the surface 3a of the front panel 3 to prevent scratches and dirt from adhering to the screen display portion 8a. The push-type switch 16 can be appropriately operated while appropriately avoiding deterioration of the visibility and appearance of the display surface 4.

Further, as compared with the case where the adhesive layer 13 is adhered to the entire surface 7a of the overlay cover 7, it is possible to reduce the area where adhesive residue may occur when the protective film 10 adhered to the surface 7a of the overlay cover 7 is peeled off. As a result, it is possible to prevent deterioration of the appearance due to the generation of adhesive residue.

Further, when the decoration method is different between the surface 7a of the overlay cover 7 and the upper surface 17a of the push plate 17 of the push-type switch 16, in a configuration in which the adhesive layer 13 is adhered to the upper surface 17a of the push plate 17 and the periphery of the upper surface 17a, it is necessary to evaluate the resistance to the adhesive layer 13 and the adhesive residue resistance for both the surface 7a of the overlay cover 7 and the upper surface 17a of the push plate 17. On the other hand, the resistance to the adhesive layer 13 and the resistance to adhesive residue may be evaluated only on the upper surface 17a of the push plate 17. Therefore, it is possible to reduce the development cost and development period, and to improve the development efficiency.

Further, since the adhesive layer 13 is prevented from adhering not only to the upper surface 17a of the push plate 17 of the push type switch 16 and the periphery of the upper surface 17a thereof but also to the screen display portion 8a facing the display surface 4, it is also possible to appropriately avoid deterioration of the visibility and appearance of the display surface 4 due to the generation of bubbles and wrinkles.

Further, the adhesive layer 13 is adhered to the surface 7a of the overlay cover 7 at two opposite locations in the left-right direction. For example, when the right end of the protective film 10 is held by the right hand and the left end is held by the left hand and the protective film 10 is adhered to the surface 3a of the front panel 3, it becomes easy to evenly adjust the left-right balance and it is possible to improve a workability when the protective film 10 is adhered.

Further, conventionally, the protective film 10 can be attached only after confirming the operation of the push-type switch 16 in the manufacturing process or the inspection process, and therefore, there is concern that scratches and dirt would adhere to the screen display portion 8a in the manufacturing process or the inspection process. However, in the present embodiment, the protective film 10 can be attached even before the operation of the push-type switch 16 is confirmed, and it is possible to appropriately prevent scratches and dirt from adhering to the screen display portion 8a in the manufacturing process and the inspection process. It is also possible to increase the degree of freedom in the procedure of the manufacturing process and the inspection process. Further, when it becomes necessary to check the operation of the push-type switch 16 after the protective film 10 is attached, it has been necessary to partially peel off the protective film 10 in some case, but in the present embodiment, it is not necessary to partially peel off the protective film 10.

Although the present disclosure has been described in accordance with the examples, it is understood that the present disclosure is not limited to such examples or structures. The present disclosure encompasses various modifications and variations within the scope of equivalents. Additionally, various combinations and configurations, as well as other combinations and configurations including more, less, or only a single element, are within the scope and spirit of the present disclosure.

The electronic equipment is not limited to the center display device 2, and may be another in-vehicle device. Further, it may be an electronic equipment for other purposes other than the in-vehicle use.

The layout and number of rotary switches and push switches are arbitrary. The layout, shape, area ratio, etc. of the portion peeled from the adhesive layer 13 and the portion remaining without being peeled from the adhesive layer 13 may be determined in the separator 11 according to the layout and number of push-type switches.

Although the configuration in which the display surface 4 is covered by the screen display portion 8a of the overlay cover 7 on the surface 3a of the front panel 3 is illustrated, the configuration in which the display surface 4 is exposed may be possible.

What is claimed is:

1. A protective member, comprising:
a protective film having a base material layer and an adhesive layer on which an adhesive is applied to the base material layer; and
a separator configured to attach to an entire surface of the adhesive layer before the protective film is used, and the separator configured in which a part is peeled off from the adhesive layer and the rest is not peeled off when the protective film is used, wherein
a front panel has an overlay cover provided with a display surface and an opening, in which an upper surface of a push plate of a push-type switch is exposed from the opening and the upper surface of the push plate of the push-type switch and a surface of the overlay cover are almost flush,
when the protective film is attached to a surface of the front panel, the adhesive layer is adhered to a part of the surface of the overlay cover, and the protective film is attached to the surface of the front panel so that the adhesive layer is not adhered to the upper surface of the push plate of the push-type switch and a periphery of the upper surface.

2. The protective member according to claim 1, wherein
the separator is not peeled from the adhesive layer at the upper surface of the push plate of the push-type switch and a portion corresponding to the periphery of the upper surface, and the protective film is attached to the surface of the front panel so that the adhesive layer is not adhered to the upper surface of the push plate of the push-type switch and the periphery of the upper surface.

3. The protective member according to claim 2, wherein
a screen display portion facing the display surface is provided on the overlay cover, and
the protective film is attached to the surface of the front panel so that the separator is not peeled from the adhesive layer even in the portion corresponding to the screen display portion and the adhesive layer is not adhered to the screen display portion.

4. The protective member according to claim 1, wherein
the protective film is attached to the surface of the front panel so that the adhesive layer is adhered at a plurality of locations facing each other on the surface of the overlay cover.

5. The protective member according to claim 4, wherein
the protective film is attached to the surface of the front panel so that the adhesive layer is adhered at a plurality of locations facing each other in a left-right direction on the surface of the overlay cover.

6. The protective member according to claim 1, wherein
a slit is formed in a portion of the separator that is not peeled off from the adhesive layer.

7. An electronic equipment, comprising:
a front panel having an overlay cover provided with a display surface and an opening, in which an upper surface of a push plate of a push-type switch is exposed from the opening and the upper surface of the push plate of the push-type switch and a surface of the overlay cover are almost flush;
a protective film having a base material layer and an adhesive layer on which an adhesive is applied to the base material layer; and
a separator configured to attach to an entire surface of the adhesive layer before the protective film is used, and the separator configured in which a part is peeled off from the adhesive layer and the rest is not peeled off when the protective film is used, wherein
the protective film is attached to a surface of the front panel so that the adhesive layer is adhered to a part of a surface of the overlay cover and the adhesive layer is not adhered to the upper surface of the push plate of the push-type switch and a periphery of the upper surface.

8. The electronic equipment according to claim 7, wherein
the separator is not peeled from the adhesive layer at the upper surface of the push plate of the push-type switch and a portion corresponding to the periphery of the upper surface, and the protective film is attached to the surface of the front panel so that the adhesive layer is not adhered to the upper surface of the push plate of the push-type switch and the periphery of the upper surface.

9. The electronic equipment according to claim 8, wherein
a screen display portion facing the display surface is provided on the overlay cover, and
the protective film is attached to the surface of the front panel so that the separator is not peeled from the adhesive layer even in the portion corresponding to the screen display portion and the adhesive layer is not adhered to the screen display portion.

10. The electronic equipment according to claim 7, wherein
the protective film is attached to the surface of the front panel so that the adhesive layer is adhered at a plurality of locations facing each other on the surface of the overlay cover.

11. The electronic equipment according to claim 10, wherein
the protective film is attached to the surface of the front panel so that the adhesive layer is adhered at a plurality of locations facing each other in a left-right direction on the surface of the overlay cover.

12. The electronic equipment according to claim 7, wherein
a slit is formed in a portion of the separator that is not peeled off from the adhesive layer.
